(19) United States
(12) Patent Application Publication
(10) Pub. No.: US 2026/0305073 A1
(43) Pub. Date: Oct. 1, 2026

(54) DISPLAY APPARATUS

(71) Applicant: LG Display Co., Ltd., Seoul (KR)

(72) Inventor: Seonhyeon LEE, Paju-si (KR)

(73) Assignee: LG Display Co., Ltd., Seoul (KR)

(21) Appl. No.: 19/420,035

(22) Filed: Dec. 15, 2025

(30) Foreign Application Priority Data
Mar. 31, 2025 (KR) 10-2025-0041126

(51) Int. Cl. H10K 59/121; H10K 59/131; H10K 59/95

(52) U.S. Cl. CPC H10K 59/1213; H10K 59/131; H10K 59/95

(57) ABSTRACT

A display apparatus includes a substrate having a display area and a non-display area adjacent to the display area, the non-display area including a circuit mounting area; a pixel part having a plurality of pixels in the display area; and a driving integrated circuit disposed in the circuit mounting area and electrically connected to the pixel part. One or more of a corner portion of the driving integrated circuit and the circuit mounting area corresponding to the corner portion includes a chamfer part configured to distribute stress generated during bending of the substrate. The chamfer part reduces the concentration of mechanical stress and prevents or minimizes cracks or delamination occurring around the driving integrated circuit, thereby improving the reliability of the display apparatus and maintaining stable performance under bending or environmental stress conditions.

### CROSS-REFERENCE TO RELATED APPLICATION

This application claims the benefit of and priority to Korean Patent Application No. 10-2025-0041126 filed on Mar. 31, 2025, the entirety of which is hereby incorporated by reference for all purposes as if fully set forth herein.

### BACKGROUND

### Technical Field

The present disclosure relates to a display apparatus.

### Description of the Related Art

In display apparatus, a liquid crystal display apparatus, a light emitting display apparatus, and an electrophoresis display apparatus may be thinned, and thus, research and development for implementing the display apparatus as a flexible display apparatus are being done. In the flexible display apparatus, lines and a display part or the like including a thin film transistor (TFT) are provided on a flexible substrate having flexibility, and even when being bent like paper, an image may be displayed. Accordingly, the flexible display apparatus may be applied to various display fields.

The flexible display apparatus using a flexible display panel may decrease a non-display area (or a bezel area) through bending of a bending area, and thus, are being widely used as display screens of various electronic devices.

### BRIEF SUMMARY

The flexible display apparatus includes a driving integrated circuit mounted on the flexible display panel. The manufacturing process of the flexible display apparatus includes a reliability test conducted under conditions of elevated temperature and humidity, or under a high-temperature environment.

It has been identified that cracks may occur around the driving integrated circuit when the flexible display panel is bent during the reliability test performed under such conditions. To address this issue, extensive experimentation has been carried out, resulting in the development of a display apparatus having a structure that can prevent or substantially reduce the occurrence of cracks or delamination around the driving integrated circuit.

To be specific, the present disclosure relates to a flexible display apparatus that enhances structural reliability by preventing cracks or delamination around a driving integrated circuit during bending or exposure to high temperature and humidity. The apparatus includes a chamfer part formed at one or more corners of the integrated circuit or at a corresponding area of the substrate. The chamfer, which may have a curved or inclined surface, serves to distribute mechanical stress that would otherwise concentrate at the circuit corners, thereby reducing damage to surrounding insulating layers.

In addition, the apparatus includes resin and auxiliary resin layers surrounding the integrated circuit. These layers, which may be composed of the same thermosetting or photo-curable material as the anisotropic conductive film adhesive, extend to cover the lower side surfaces of the circuit and act as stress absorbing buffers. The anisotropic conductive film provides both electrical connection and mechanical stability, and its slightly larger area relative to the circuit further assists in dispersing localized stress.

Through these structural arrangements, the display apparatus achieves improved mechanical durability under environmental stress while maintaining a reduced bezel area suitable for compact and flexible devices. The structure also promotes higher reliability and supports environmentally and economically efficient manufacturing by minimizing defect occurrence during production and reliability testing.

One or more embodiments of the present disclosure are directed to providing a display apparatus capable of preventing or minimizing cracks and/or peeling (or delamination) occurring around the driving integrated circuit.

One or more embodiments of the present disclosure are directed to providing a display apparatus having improved reliability.

One or more embodiments of the present disclosure are directed to providing a display apparatus capable of realizing ESG (Environmental, Social, Governance) performance through process optimization due to a crack (or peeling or delamination) prevention structure.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a display apparatus comprises a substrate having a display area, a non-display area surrounding the display area, and a circuit mounting area provided in the non-display area; a pixel part having a plurality of pixels in the display area of the substrate; and a driving integrated circuit disposed in the circuit mounting area of the substrate and electrically connected to the pixel part. One or more of a corner portion of the driving integrated circuit and the circuit mounting area corresponding to the corner portion of the driving integrated circuit includes a chamfer part.

Details of other exemplary embodiments will be included in the detailed description of the disclosure and the accompanying drawings.

According to a means for solving the problems of the present disclosure, in the display apparatus according to one or more embodiments of the present disclosure, cracks and/or peeling (or delamination) occurring around the driving integrated circuit may be prevented or minimized.

According to a means for solving the problems of the present disclosure, a display apparatus according to one or more embodiments of the present disclosure may have improved reliability.

The display apparatus according to one or more embodiments of the present disclosure may realize ESG (Environmental, Social, Governance) performance through process optimization due to a crack (or peeling or delamination) prevention structure.

Other systems, methods, features and advantages will be, or will become, apparent to one with skill in the art upon examination of the following FIGs. and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure. However, the technical features of the present embodiment are not limited to those shown in the specific drawings, and the features disclosed in each drawing may be combined to form a new embodiment.

FIG. 1 is a plan view illustrating a display apparatus according to an embodiment of the present disclosure.

FIG. 2 is a cross-sectional view illustrating a display apparatus according to an embodiment of the present disclosure.

FIG. 3 is an enlarged view schematically illustrating a portion “A” illustrated in FIG. 2.

FIG. 4 is an enlarged view schematically illustrating a portion “B” illustrated in FIG. 1.

FIG. 5 is a cross-sectional view taken along line I-I′ illustrated in FIG. 4.

FIG. 6 is another enlarged view schematically illustrating a portion “B” illustrated in FIG. 1.

FIG. 7 is another enlarged view schematically illustrating a portion “B” illustrated in FIG. 1.

FIG. 8 is a cross-sectional view taken along line II-II′ illustrated in FIG. 7.

FIG. 9 is another enlarged view schematically illustrating a portion “B” illustrated in FIG. 1.

FIG. 10A illustrates a stress applied to an inorganic insulating layer around a corner portion of a driving integrated circuit in a display apparatus according to an experimental example.

FIG. 10B illustrates a stress applied to an inorganic insulating layer around a corner portion of a driving integrated circuit in a display apparatus according to an embodiment of the present disclosure described with reference to FIG. 4.

FIG. 10C illustrates a stress applied to an inorganic insulating layer around a corner portion of a driving integrated circuit in a display apparatus according to another embodiment of the present disclosure described with reference to FIG. 9.

FIG. 11A illustrates peeling damage between a substrate and an inorganic insulating layer around a corner portion of a driving integrated circuit in a display apparatus according to an experimental example.

FIG. 11B illustrates peeling damage between a substrate and an inorganic insulating layer around a corner portion of a driving integrated circuit in a display apparatus according to an embodiment of the present disclosure described with reference to FIG. 4.

FIG. 11C illustrates peeling damage between a substrate and an inorganic insulating layer around a corner portion of a driving integrated circuit in a display apparatus according to another embodiment of the present disclosure described with reference to FIG. 9.

Throughout the drawings and the detailed description, unless otherwise described, the same drawing reference numerals should be understood to refer to the same elements, features, and structures.

### DETAILED DESCRIPTION

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present disclosure are used, another part may be added unless “only” is used. The terms of a singular form can include plural forms unless referred to the contrary.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of a display apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

The display apparatus according to an embodiment of the present disclosure may be a flexible display apparatus, a display panel, or a flexible display panel, but is not limited thereto. For example, the display apparatus according to an embodiment of the present disclosure may include a set electronic apparatus or a set device (or a set apparatus) such as a notebook computer, a television, a computer monitor, an equipment apparatus including an automotive apparatus or another type apparatus for vehicles, or a mobile electronic apparatus such as a smartphone or an electronic pad, which is a complete product (or a final product) including a liquid crystal display panel or an organic light emitting display panel, or the like.

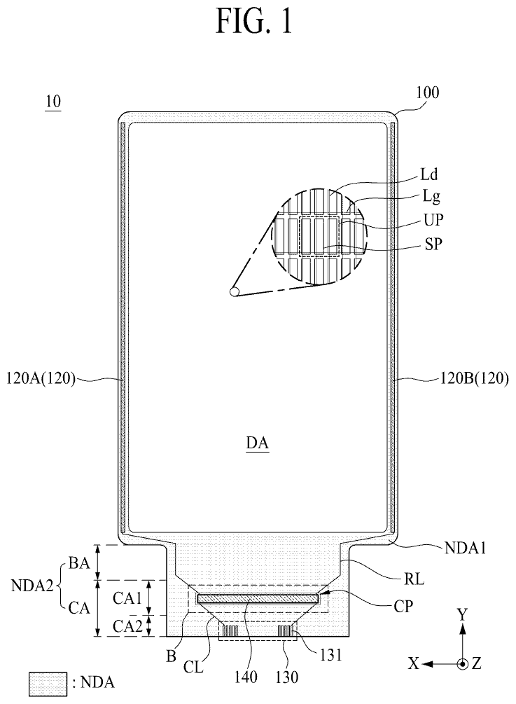

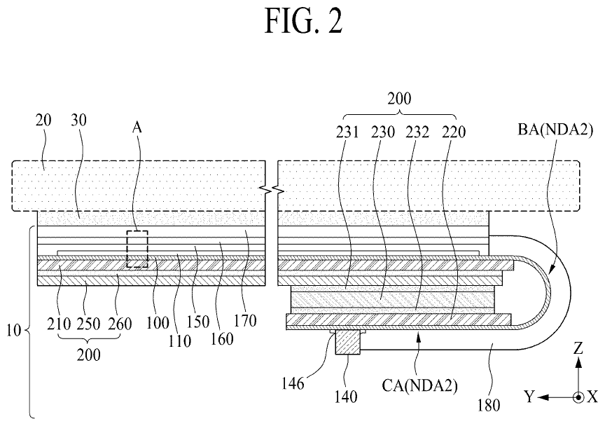

FIG. 1 is a plan view illustrating a display apparatus according to an embodiment of the present disclosure. FIG. 2 is a cross-sectional view illustrating a display apparatus according to an embodiment of the present disclosure.

Referring to FIGS. 1 and 2, the display apparatus (or a display panel) 10 according to an embodiment of the present disclosure may include a shape where a portion thereof is bent as illustrated in FIG. 2. FIG. 1 illustrates a shape where the display apparatus (or the display panel) 10 according to an embodiment of the present disclosure is not bent.

The display apparatus (or a display panel) 10 according to an embodiment of the present disclosure may include a substrate 100 which includes a display area DA and a non-display area NDA.

The substrate 100 may be a base member or a base substrate for supporting or forming several elements of the display apparatus 10. The substrate 100 may be made of a material having flexibility.

The display area DA may be an area which displays an image. The non-display area NDA may be an area which does not display an image. The non-display area NDA may be a peripheral region of the display area DA. The non-display area NDA may be implemented to surround the display area DA. For example, the non-display area NDA may include an edge portion of the substrate 100. For example, the display area DA may be a flat region or a flat portion.

The non-display area NDA according to an embodiment of the present disclosure may include a first non-display area NDA1 and a second non-display area NDA2.

The first non-display area NDA1 may be implemented to surround the display area DA. The first non-display area NDA1 may include a region which extends to have a certain width from each side of the display area DA. The first non-display area NDA1 may be a flat region or a flat portion. The first non-display area NDA1 may be a first flat region or a first flat portion together with the display area DA.

The first non-display area NDA1 may include a pair of short-side regions parallel to a first direction X and a pair of long-side regions parallel to a second direction Y intersecting with the first direction X. For example, the pair of long-side regions of the first non-display area NDA1 may be folded or bent toward a rear surface of the display area DA, and thus, the display apparatus may decrease in bezel width of the long-side region. For example, the pair of long-side regions of the first non-display area NDA1 may be a long-side bending area or a bezel bending area.

A long-side region of the display area DA adjacent to the pair of long-side regions of the first non-display area NDA1 may be bent to have a certain curvature together with the pair of long-side regions of the first non-display area NDA1. For example, the long-side region of the display area DA having the certain curvature may be an active bending area, a curved display area, or a bending display area.

The second non-display area NDA2 may include an area which extends from one side of the first non-display area NDA1. The second non-display area NDA2 may include an area which extends from at least a portion of one short side of the first non-display area NDA1 to have a certain length along the second direction Y. The second non-display area NDA2 may extend from a center portion of the one short side of the first non-display area NDA1 to have a certain width and a certain length.

The second non-display area NDA2 according to an embodiment of the present disclosure may include a bending area BA and a circuit area CA.

The bending area BA may include an area which extends from one side of the first non-display area NDA1. The bending area BA may be bent from the one side of the first non-display area NDA1 to have a certain curvature. For example, the bending area BA may be bent toward a rear surface of the first non-display area NDA1 (or a substrate 100) from the one side of the first non-display area NDA1, but is not limited thereto.

The circuit area CA may extend along the second direction Y from the bending area BA. The circuit area CA may be disposed to overlap the display area DA. The circuit area CA may be disposed under a rear surface of the substrate 100 and may face the rear surface of the substrate 100.

The circuit area CA may include a circuit mounting area CA1 and a pad area CA2 which extend along the second direction Y from the bending area BA.

The circuit mounting area CA1 may be formed on the substrate 100 between the bending area BA and the pad area CA2. The circuit mounting area CA1 may be an integrated circuit arrangement area or a chip mounting area.

The pad area CA2 may extend from the circuit mounting area CA1 along the second direction Y. The pad area CA2 may be a circuit connection portion, a circuit connection part, a circuit connection area, a circuit coupling area, or a signal input/output area.

The display apparatus (or the display panel) 10 according to an embodiment of the present disclosure may further include a pixel part 110, a gate driving circuit 120, a pad part 130, and a driving integrated circuit 140.

The pixel part 110 may be implemented in the display area DA of the substrate 100 and may display a black image or a color image. For example, the pixel part 110 may be a pixel layer, a pixel array, a pixel array layer, or a pixel array part.

The pixel part 110 may include a plurality of pixels UP disposed in the display area DA. The plurality of pixels UP may be respectively implemented in pixel areas provided by a plurality of gate lines Lg and a plurality of data lines Ld.

When the display apparatus 10 according to an embodiment of the present disclosure is a light emitting display apparatus, the pixel part 110 may be configured to include a light emitting device having an emission structure. For example, the emission structure may include a light emitting layer (or an organic light emitting layer), but is not limited thereto, and the emission structure may include an inorganic light emitting layer (or an inorganic light emitting diode). When the display apparatus 10 according to an embodiment of the present disclosure is a liquid crystal display (LCD) apparatus, the pixel part 110 may be configured to include a liquid crystal layer. Hereinafter, for convenience of description, it may be assumed that the display apparatus 10 is an organic light emitting display apparatus, but is are not limited thereto.

Each of the plurality of pixels UP may be configured to implement a black image or a color image. One pixel UP may be a unit pixel. Each of the plurality of pixels UP may include a plurality of subpixels SP. For example, each of the plurality of subpixels SP may be configured to implement one of a plurality of colors (or light) implementing a color image (or color light).

Each of the plurality of subpixels SP may include a pixel circuit having one or more thin film transistors, and a light emitting device electrically connected to the pixel circuit. For example, each of the plurality of subpixels SP may be configured to include a light emitting device implementing any one of red light, green light, blue light, and white light. For example, each of the plurality of pixels UP may implement an image through a plurality of subpixels SP arranged as a stripe scheme, or may implement an image through a plurality of subpixels SP arranged as a pentile scheme.

The gate driving circuit 120 may be implemented in the non-display area NDA adjacent to the display area DA so as to be electrically connected to the pixel part 110. The gate driving circuit 120 may be implemented in a long-side region of the first non-display area NDA1 so as to be electrically connected to the pixel part 110. For example, the gate driving circuit 120 may be implemented in one or more of a pair of long-side regions of the first non-display area NDA1 so as to be electrically connected to a plurality of gate lines disposed in the pixel part 110.

The gate driving circuit 120 may be directly formed or implemented on the substrate 100 by a manufacturing process of a thin film transistor of the pixel, based on a GIP (gate in panel) scheme. For example, the gate driving circuit 120 may be a gate embedded circuit or a gate shift register circuit, but is not limited thereto.

The gate driving circuit 120 may include one or more of a first gate driving circuit 120A and a second gate driving circuit 120B.

The first gate driving circuit 120A may be implemented in a first long-side region of the first non-display area NDA1 adjacent to a first side (or one side) of the display area DA. The second gate driving circuit 120B may be implemented in a second long-side region of the first non-display area NDA1 adjacent to a second side (or the other side), which is opposite to the first side (or the one side), of the display area DA.

According to an embodiment of the present disclosure, the first gate driving circuit 120A may be electrically connected to one end of each of a plurality of gate lines, and the second gate driving circuit 120B may be electrically connected to the other end of each of a plurality of gate lines provided in the pixel part 110. According to another embodiment of the present disclosure, the first gate driving circuit 120A may be electrically connected to one end of each of odd-numbered (or even-numbered) gate lines of the plurality of gate lines, and the second gate driving circuit 120B may be electrically connected to the other end of each of even-numbered (or odd-numbered) gate lines of the plurality of gate lines provided in the pixel part 110.

The pad part 130 may be implemented in the non-display area NDA of the substrate 100. The pad part 130 may be implemented in the pad area CA2 of the second non-display area NDA2. The pad part 130 may be implemented in an end region of the second non-display area NDA2.

The pad part 130 may receive image data and a timing synchronization signal supplied from a display driving system (or a host driving circuit). The pad part 130 may include a plurality of pads 131 which are disposed at a predetermined interval along the first direction X. The pad part 130 may include a power pad part, a display data pad part, a control signal pad part, a timing signal pad part, and a touch data pad part. For example, each of the power pad part, the display data pad part, the control signal pad part, the timing signal pad part, and the touch data pad part may be configured to include one or more of the plurality of pads 131.

The driving integrated circuit 140 may be mounted or disposed in the non-display area NDA of the substrate 100. The driving integrated circuit 140 may be disposed (or mounted) in the circuit mounting area CA1 of the second non-display area NDA2. For example, the driving integrated circuit 140 may be disposed (or mounted) in the circuit mounting area CA1 of the substrate 100 by a chip bonding process using an anisotropic conductive film or the like.

The driving integrated circuit 140 may include a plurality of input channels (or bumps) and a plurality of output channels (or bumps).

Each of the plurality of input channels may be electrically connected to the pad part 130 through the plurality of pad connection lines CL. For example, the plurality of pad connection lines CL may be disposed between the driving integrated circuit 140 and the pad part 130 and may be connected (or coupled) in a one-to-one relationship between the plurality of input channels and the plurality of pads 131.

Each of the plurality of output channels may be electrically connected to the plurality of data lines Ld and the gate driving circuit 120 through the plurality of routing lines RL. For example, the plurality of routing lines RL may be disposed in the bending area BA of the substrate 100 and may be electrically connected between each of the plurality of data lines Ld and the gate driving circuit 120 and the plurality of output channels.

The driving integrated circuit 140 may generate and output a data signal and a gate control signal, based on the image data and the timing synchronization signal supplied through the pad part 130 from the display driving system. The data signal may be supplied to the data lines of the pixel part 110, and the gate control signal may be supplied to the gate driving circuit 120.

The gate control signal may include one or more gate start signals, a plurality of gate shift clocks, and a plurality of gate driving voltages. Therefore, in response to the gate control signal supplied from the driving integrated circuit 140, the gate driving circuit 120 may generate a gate signal (or a gate pulse) according to a predetermined order and may supply the gate signal to a corresponding gate line.

The driving integrated circuit 140 may generate and output various driving powers (or driving voltages) needed for displaying an image on the pixel part 110, based on an input power (or an input voltage) supplied through the pad part 130 from the display driving system.

The driving integrated circuit 140 may be configured to include various circuits needed for displaying an image on the pixel part 110. For example, the driving integrated circuit 140 may include various integrated circuits (ICs) and driving circuits such as a gate control signal generating circuit, a data signal generating circuit, a power generating circuit, and a clock generating circuit. For example, the driving integrated circuit 140 may be a driving IC or an integration driving IC, but is not limited thereto.

The display apparatus (or the display panel) 10 according to an embodiment of the present disclosure may further include a test circuit part disposed under the driving integrated circuit 140.

The test circuit part may include a plurality of test thin film transistors electrically connected to the plurality of data lines disposed in the pixel part 110, one or more enable signal pads, and one or more test signal pads. In a test process performed before the driving integrated circuit 140 is mounted on the substrate 100, each of the plurality of test thin film transistors may be turned on by an enable signal applied through an enable signal pad and may supply a test signal, applied through a test signal pad, to each of the plurality of data lines.

The display apparatus (or the display panel) 10 according to an embodiment of the present disclosure may further include an encapsulation part 150 which covers or surrounds the pixel part 110. The encapsulation part 150 may be configured to protect the pixel part 110. For example, the encapsulation part 150 may be configured to prevent external oxygen or water from penetrating into a display element of the pixel part 110.

The display apparatus (or the display panel) 10 according to an embodiment of the present disclosure may further include a touch sensing part 160.

The touch sensing part 160 may be disposed or provided on the encapsulation part 150. For example, the touch sensing part 160 may be directly formed or provided at the encapsulation part 150. The touch sensing part 160 may include a touch sensor which senses a user touch. The touch sensing part 160 according to an embodiment of the present disclosure may include a plurality of touch driving electrodes and a plurality of touch sensing electrodes for sensing a touch on the basis of a mutual capacitance type. The touch sensing part 160 according to another embodiment of the present disclosure may include a plurality of touch electrodes (or touch sensing electrodes) for sensing a touch on the basis of a self-capacitance type.

The display apparatus (or the display panel) 10 according to an embodiment of the present disclosure may include a functional film 170.

The functional film 170 may be attached on the sensing part 160. The functional film 170 may include a reflection preventing layer to prevent reflection of external light in order to improve contrast ratio and outdoor visibility for an image displayed on the display apparatus.

The display apparatus (or the display panel) 10 according to an embodiment of the present disclosure may further include a cover layer 180 which covers the bending area BA of the substrate 100.

The cover layer (or a micro cover layer) 180 may be formed to cover the bending area BA of the substrate 100 and a peripheral region of the bending area BA. For example, the cover layer 180 may be coated on the bending area BA of the substrate 100 and the peripheral region of the bending area BA. The cover layer 180 may be formed to cover the routing lines RL disposed in the second non-display area NDA2 of the substrate 100 corresponding to a region between the driving integrated circuit 140 and the encapsulation part 150 on the substrate 100.

The cover layer 180 may include a polymer material. The cover layer 180 may protect routing lines RL, which are in the bending area BA, from an external impact and may prevent water from penetrating into the routing lines. For example, when the bending area BA of the substrate 100 is bent in a curved shape, the cover layer 180 may enable routing lines RL to be positioned on a neutral plane of the bending area BA. Therefore, the routing lines RL in the bending area BA may be positioned on the neutral plane between the cover layer 180 and the substrate 100, and thus, when the bending area BA of the substrate 100 is bent in a curved shape, a bending stress of 0 (zero) may be applied to the routing lines, whereby the routing lines may be bent without being damaged by the bending stress.

The display apparatus (or the display panel) 10 according to an embodiment of the present disclosure may further include a supporting member 200.

The supporting member 200 may be configured to support the other portion, except the bending area BA, of the substrate 100. The supporting member 200 may maintain the other portion, except the bending area BA, of the substrate 100 in a flat state.

The supporting member 200 according to an embodiment of the present disclosure may include a first supporting plate 210, a second supporting plate 220, and a coupling member 230.

The first supporting plate 210 may be configured to support a rear surface (or a backside surface) of the substrate 100 overlapping the display area DA. For example, the first supporting plate 210 may be coupled to or attached on the rear surface (or the backside surface) of the substrate 100 overlapping the display area DA and the first non-display area NDA1. The first supporting plate 210 may maintain the display area DA and the first non-display area NDA1 in a flat state.

The second supporting plate 220 may be configured to support a rear surface (or a backside surface) of the substrate 100 overlapping the circuit area CA of the non-display area NDA. For example, the second supporting plate 220 may be coupled to or attached on the rear surface (or the backside surface) overlapping the remaining circuit area CA other than the bending area BA among the second non-display area NDA2 of the non-display area NDA. The second supporting plate 220 may maintain the circuit area CA of the non-display area NDA in a flat state.

The first and second supporting plates 210 and 220 may include a plastic material, but is not limited thereto.

The bending area BA of the substrate 100 may be disposed between the first supporting plate 210 and the second supporting plate 220. The bending area BA of the substrate 100 may not be supported by each of the first supporting plate 210 and the second supporting plate 220, and thus, may be freely bent. Therefore, the bending area BA of the substrate 100 may be bent to surround one lateral surface of the first supporting plate 210, and the circuit area CA of the substrate 100 may be disposed on the rear surface (or the backside surface) of the substrate 100 overlapping the display area DA of the substrate 100. Accordingly, the display apparatus according to an embodiment of the present disclosure may decrease in bezel width which occurs due to the second non-display area NDA2 of the non-display area NDA, and thus, may have a thin bezel width.

The coupling member 230 may be connected or coupled between the first supporting plate 210 and the second supporting plate 220. The coupling member 230 may couple or fix the second supporting plate 220 to the rear surface (or the backside surface) of the first supporting plate 210, and thus, may bend the bending area BA of the substrate 100 at a certain curvature (or a curvature radius) and may maintain a bending state and a bending shape of the bending area BA of the substrate 100.

The coupling member 230 may be disposed between the first supporting plate 210 and the second supporting plate 220 overlapping each other, with respect to a thickness direction Z of the substrate 100. The coupling member 230 may fix the second supporting plate 220, disposed on a rear surface of the first supporting plate 210, to a rear (or backside) edge portion of the first supporting plate 210, based on bending of the bending area BA of the substrate 100, and thus, may maintain a bending state and a bending shape of the bending area BA of the substrate 100.

A first surface of the coupling member 230 may be attached on the rear edge portion of the first supporting plate 210 by a first attachment member 231. A second surface of the coupling member 230 may be attached on a rear surface of the second supporting plate 220 by a second attachment member 232.

The supporting member 200 according to an embodiment of the present disclosure may further include a rear member 250.

The rear member 250 may be coupled to or attached on the rear surface of the first supporting plate 210. For example, the rear member 250 may be coupled to or attached on the rear surface of the first supporting plate 210 by an adhesive member 260.

The rear member 250 according to an embodiment of the present disclosure may be coupled to or attached on an entire rear surface of the first supporting plate 210. Accordingly, the coupling member 230 or the first surface of the coupling member 230 may be attached on a rear edge portion of the rear member 250 by the first attachment member 231.

The rear member 250 may include a metal material. For example, the rear member 250 may include a metal layer. For example, the rear member 250 may include a metal plate including a metal material which is good in thermal conductivity. For example, the rear member 250 may function as a noise prevention layer which prevents static electricity or frequency noise, occurring in the display driving system connected to the pad part 130, from penetrating into the pixel part 110. For example, the rear member 250 may be a heat dissipation member, a heat dissipation plate, a shield member, a signal blocking member, a heat dissipation tape, a heat dissipation cushion tape, a conductive heat dissipation tape, a heat dissipation sheet, a heat dissipation ground sheet, or a conductive heat dissipation sheet.

The display apparatus (or the display panel) 10 according to an embodiment of the present disclosure may be connected to or coupled to a rear surface of a cover member 20 by a connection member 30. The cover member 20 may be implemented to cover an entire front surface of the display apparatus 10. For example, the cover member 20 may have a size which is greater than that of the display apparatus 10. For example, the cover member 20 may be attached on or coupled to the functional film 170 of the display apparatus 10 by the connection member 30. Accordingly, the cover member 20 may cover the functional film 170 of the display apparatus 10 and the bending area BA bent in a curved shape, and thus, may protect the display apparatus 10 from an external impact or may prevent an impact from being applied to the bending area BA bent in a curved shape.

The cover member 20 may be made of a transparent plastic material, a glass material, or a tempered glass material. The connection member 30 may be an adhesive layer or a tacky layer.

The display apparatus 10 or the display panel according to an embodiment of the present disclosure may further include a chamfer part CP configured at one or more of a corner portion of the driving integrated circuit 140 and the circuit mounting area CA1 corresponding to the corner portion of the driving integrated circuit 140. For example, the chamfer part CP may be a crack (or peeling or delamination) prevention portion or a crack (or peeling or delamination) prevention member configured to prevent or minimize cracks and/or peeling (or delamination) occurring around the driving integrated circuit 140, but is not limited thereto. For example, the chamfer part CP may be configured to distribute (or disperse) stress concentrated on the corner portion of the driving integrated circuit 140 due to bending of the display panel or the substrate 100, thereby preventing or minimizing cracks and/or peeling (or delamination) occurring in an insulating layer which is disposed (or formed) around the driving integrated circuit 140 due to the bending of the substrate 100.

As an embodiment, the chamfer part CP may be formed (or configured) at the corner portion of the driving integrated circuit 140. For example, the driving integrated circuit 140 may be configured to include the chamfer part CP formed at the corner portion thereof. As another embodiment, the chamfer part CP may be formed (or configured) at the circuit mounting area CA1 corresponding to the corner portion of the driving integrated circuit 140. For example, the chamfer part CP may be formed (or configured) at a corner portion of the circuit mounting area CA1 corresponding to the corner portion of the driving integrated circuit 140 so as to surround the corner portion of the driving integrated circuit 140. The chamfer part CP will be described in more detail below.

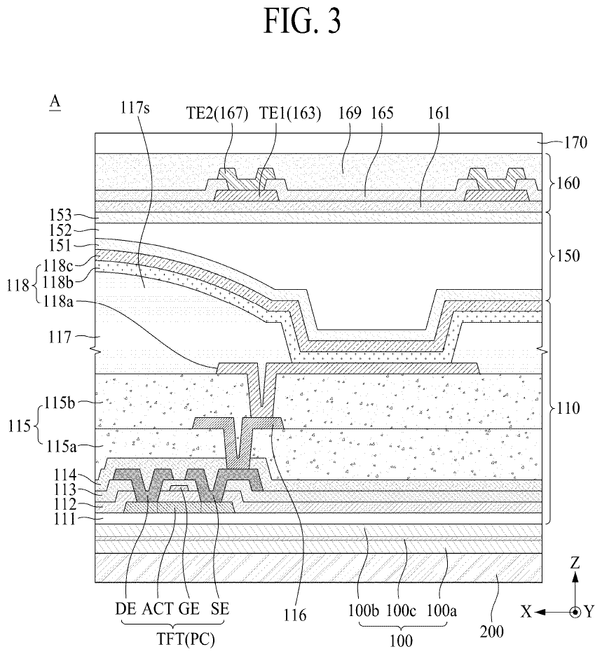

FIG. 3 is an enlarged view schematically illustrating a portion “A” illustrated in FIG. 2. FIG. 3 is a cross-sectional view schematically illustrating one subpixel illustrated in FIGS. 1 and 2.

Referring to FIGS. 1 to 3, the display apparatus 10 or the display panel according to an embodiment of the present disclosure may include the substrate 100, the pixel part 110, and the encapsulation part 150.

The substrate 100 may include one or more plastic material layer. For example, the substrate 100 may include a first base substrate 100a and a second base substrate 100b stacked on the first base substrate 100a. Each of the first and second base substrates 100a and 100b may include a plastic material such as polyimide or the like.

The substrate 100 may include a middle layer 100c which is disposed or interposed between the first base substrate 100a and the second base substrate 100b. The middle layer 100c may be configured to prevent the penetration of water through the substrate 100. The middle layer 100c may be configured to electrically insulate the substrate 100. For example, the middle layer 100c may include an electrical insulating material. For example, the middle layer 100c may include an inorganic material.

The pixel part 110 may include a buffer layer 111, a pixel circuit PC, an overcoat layer 115, and a light emitting device layer 118.

The buffer layer 111 may be disposed on the substrate 100. The buffer layer 111 may prevent a material of the substrate 100 from being diffused to a transistor in performing a high temperature process in a manufacturing process of thin film transistors, or may prevent external water or moisture from penetrating into the light emitting device layer 118.

The pixel circuit PC may include a driving thin film transistor TFT which is provided at a pixel area on the substrate 100 or the buffer layer 111.

The driving thin film transistor TFT may include an active layer ACT, a gate electrode GE, a source electrode SE, and a drain electrode DE.

The active layer ACT may be disposed on the substrate 100 or the buffer layer 111. For example, the active layer ACT may include a semiconductor material based on metal oxide such as indium-gallium-zinc-oxide (IGZO), but is not limited thereto and may include a semiconductor material based on silicon such as amorphous silicon or polycrystalline silicon.

The active layer ACT may include a source region, a drain region, and a channel region between the source region and the drain region. The active layer ACT may be covered by a first insulation layer (or a gate insulation layer) 112.

The first insulation layer 112 may be formed in an island shape on only the channel region of the active layer ACT, or may be formed to cover an entire front surface of the buffer layer 111 or the substrate 100 including the active layer ACT. The first insulation layer 112 may be configured with a single layer of an inorganic material or a multilayer thereof.

The gate electrode GE may be disposed on the first insulation layer 112 to overlap the channel region of the active layer ACT. The gate electrode GE may be formed of a gate metal material. For example, the gate electrode GE may include a single layer or a multilayer made of a single metal material or an alloy material thereof. The gate electrode GE may be formed together with a gate line.

The gate electrode GE may be covered by the second insulation layer (or interlayer insulation layer) 113. The second insulation layer 113 may be formed on the first insulation layer 112 to cover the gate electrode GE. The second insulation layer 113 may be configured with a single layer of an inorganic material or a multilayer thereof, but is not limited thereto and may include an organic material.

The source electrode SE may be disposed on the second insulation layer 113 so as to be electrically connected to the source region of the active layer ACT. The source electrode SE may be electrically connected to the source region of the active layer ACT through a contact hole which is formed at the first insulation layer 112 and the second insulation layer 113 overlapping the source region of the active layer ACT.

The drain electrode DE may be disposed on the second insulation layer 113 so as to be electrically connected to the drain region of the active layer ACT. The drain electrode DE may be electrically connected to the drain region of the active layer ACT through a contact hole which is formed at the first insulation layer 112 and the second insulation layer 113 overlapping the drain region of the active layer ACT.

The source electrode SE and the drain electrode DE may be formed of a source/drain metal material. For example, the source electrode SE and the drain electrode DE may be configured with a conductive material which is the same as or different from that of the gate electrode GE. The source electrode SE and the drain electrode DE may be formed together with a data line.

The pixel circuit PC may further include at least one switching thin film transistor and at least one capacitor, which is disposed at the pixel area. The at least one switching thin film transistor and the at least one capacitor may be formed together with the driving thin film transistor TFT.

The driving thin film transistor TFT or the pixel circuit PC may be covered by a passivation layer 114. The passivation layer 114 may be configured with a single layer of an inorganic material including nitride silicon (SiNx) or oxide silicon (SiOx), or a multilayer thereof, but is not limited thereto and may include an organic material. The passivation layer 114 may be omitted.

The overcoat layer 115 may be disposed to cover the pixel circuit PC or the passivation layer 114. For example, the overcoat layer 115 may be implemented to planarize an upper portion of the passivation layer 114 or the pixel circuit PC and protect the pixel circuit PC. The overcoat layer 115 may be configured with an organic material.

The overcoat layer 115 may include a first planarization layer 115a and a second planarization layer 115b formed on the first planarization layer 115a. The first planarization layer 115a and the second planarization layer 115b may have the same thickness, or may have different thicknesses.

The light emitting device layer 118 may include a first electrode 118a, a light emitting device 118b, and a second electrode 118c.

The first electrode 118a may be disposed in a pattern shape on the overcoat layer 115. The first electrode 118a may be disposed on the second planarization layer 115b of the overcoat layer 115. The first electrode 118a may be electrically connected to the source electrode SE of the driving thin film transistor TFT through an electrode contact hole formed at the overcoat layer 115.

The first electrode 118a may be an anode electrode (or a cathode electrode). For example, when the display apparatus 10 according to an embodiment of the present disclosure has a top emission structure, the first electrode 118a may be a reflection electrode which reflects light incident from the light emitting device 118b. When the display apparatus 10 according to another embodiment of the present disclosure has a bottom emission structure, the first electrode 118a may be a transparent electrode which transmits the light incident from the light emitting device 118b.

The light emitting device 118b may be disposed on the first electrode 118a. The light emitting device 118b according to an embodiment of the present disclosure may include one or more emission structure which are stacked on the first electrode 118a in the order or reverse order of a hole layer, a light emitting layer, and an electron layer. The light emitting device 118b may be implemented to generate color light corresponding to a corresponding subpixel. For example, when a unit pixel includes red, green, and blue sub-pixels, a light emitting device 118b of a red subpixel may generate red light, a light emitting device 118b of a green subpixel may generate green light, and a light emitting device 118b of a blue subpixel may generate blue light.

The light emitting device 118b according to another embodiment of the present disclosure may include a plurality of emission structures which are stacked on the first electrode 118a in the order or reverse order of a hole layer, a light emitting layer, and an electron layer. For example, the light emitting layer of each of the plurality of emission structures may generate one or more of blue light, green light, and red light or mixed light thereof. Light emitted from the light emitting device 118b may implement a color image by a color filter disposed to overlap the light emitting device layer 118. The light emitting layer of each of the plurality of emission structures may generate one or more of blue light, green light, and red light or mixed light thereof, and thus, the light emitting device 118b may emit white light. The white light emitted from the light emitting device 118b may implement a color image by a color filter disposed to overlap the light emitting device layer 118.

The second electrode 118c may be disposed on the light emitting device 118b. The second electrode 118c may be disposed on the light emitting device 118b to face the first electrode 118a with the light emitting device 118b therebetween.

The second electrode 118c may be a cathode electrode (or an anode electrode). For example, when the display apparatus 10 according to an embodiment of the present disclosure has the top emission structure, the second electrode 118c may be a transparent electrode which transmits the light incident from the light emitting device 118b. When the display apparatus 10 according to another embodiment of the present disclosure has the bottom emission structure, the second electrode 118c may be a reflection electrode which reflects the light incident from the light emitting device 118b.

The display apparatus 10 according to an embodiment of the present disclosure may further include a bank 117.

The bank 117 may be disposed to define an opening portion (or an emission region) of a subpixel SP and cover a periphery portion of the first electrode 118a. For example, the bank 117 may be disposed on the overcoat layer 115 to cover only a periphery portion, except a center portion, of the first electrode 118a. For example, the bank 117 may include a mesh shape. For example, the bank 117 may include an organic material or an inorganic material, or may include a light absorbing material including a black pigment.

A bank projection 117s may be disposed on the bank 117. The bank projection 117s may protrude from the bank 117 and may be disposed on the bank 117 with a material different from that of the bank 117. For example, the bank projection 117s may be configured to support a mask for formation of the light emitting device 118b, but is not limited thereto.

The light emitting device 118b may be disposed in only an opening portion of each subpixel SP provided by the bank 117, or may be disposed on the bank 117 and the opening portion of each subpixel SP.

The display apparatus according to an embodiment of the present disclosure may further include a connection electrode (or a middle electrode) 116 disposed in the overcoat layer 115, so as to prevent the occurrence of a pattern defect (or a contact defect) of the first electrode 118a caused by a distance between the first electrode 118a and the source electrode SE of the driving thin film transistor TFT.

The connection electrode 116 may be configured to be electrically connected to the source electrode SE of the driving thin film transistor TFT and the first electrode 118a. For example, the connection electrode 116 may be disposed on the first planarization layer 115a overlapping the source electrode SE of the driving thin film transistor TFT and may be covered by the second planarization layer 115b. The connection electrode 116 may be connected to the source electrode SE of the driving thin film transistor TFT through the electrode contact hole provided at the first planarization layer 115a. The first electrode 118a may be electrically connected to the connection electrode 116 through the electrode contact hole provided at the second planarization layer 115b. Therefore, the first electrode 118a may be stably connected to the source electrode SE of the driving thin film transistor TFT through the connection electrode 116. The connection electrode 116 may include a conductive material which is the same as or different from that of the source electrode SE and the drain electrode DE of the driving thin film transistor TFT.

According to an embodiment of the present disclosure, an additional auxiliary line (or an auxiliary signal line) for driving of the pixel circuit PC and/or emission of light from the light emitting device 118b may be disposed between the first planarization layer 115a and the second planarization layer 115b. The auxiliary line (or the auxiliary signal line) may be formed of the same material in the same process as the connection electrode 116.

The encapsulation part 150 may be configured to cover or surround the pixel part 110. For example, the encapsulation part 150 may be disposed on the light emitting device layer 118 and may cover or surround the light emitting device layer 118. The encapsulation part 150 may include at least one or more encapsulation layers. For example, the encapsulation part 150 may include one or more inorganic encapsulation layers and one or more organic encapsulation layers on the light emitting device layer 118. For example, the encapsulation part 150 may include a first encapsulation layer 151, a second encapsulation layer 152, and a third encapsulation layer 153.

The first encapsulation layer 151 may be disposed on the second electrode 118c. For example, the encapsulation part 150 may include the first encapsulation layer 151 on the second electrode 118c, the second encapsulation layer 152 on the first encapsulation layer 151, and the third encapsulation layer 153 on the second encapsulation layer 152.

The display apparatus 10 or the display panel according to an embodiment of the present disclosure may further include a touch sensing part 160 disposed on the display area DA of the substrate 100.

The touch sensing part 160 may be disposed on the encapsulation part 150. For example, the touch sensing part 160 may be disposed on the third encapsulation layer 153 of the encapsulation part 150.

The touch sensing part 160 may include a touch buffer layer 161, a first touch electrode layer 163, a touch insulation layer 165, a second touch electrode layer 167, and a touch protection layer 169.

The touch buffer layer 161 may be disposed on the third encapsulation layer 153 of the encapsulation part 150. For example, the touch buffer layer 161 may be formed of an inorganic material.

The first touch electrode layer 163 may include a plurality of first touch electrodes TE1 disposed on the touch buffer layer 161. The plurality of first touch electrodes TE1 may be made of transparent metal or opaque metal. For example, the plurality of first touch electrodes TE1 may include a plurality of bridge electrodes or a plurality of bridge lines.

The touch insulation layer 165 may be disposed on the touch buffer layer 161 to cover the first touch electrode layer 163. The touch insulation layer 165 may be formed of an inorganic material.

The second touch electrode layer 167 may include a plurality of second touch electrodes TE2 disposed on the touch insulation layer 165. The plurality of second touch electrodes TE2 may be made of transparent metal or opaque metal. For example, each of the plurality of second touch electrodes TE2 may include a mesh structure. For example, the plurality of second touch electrodes TE2 may be a plurality of touch sensing electrodes or a plurality of touch driving electrodes.

In the second touch electrode layer 167, each of the plurality of second touch electrodes TE2 disposed adjacent to one another along a first direction X or a second direction Y may be connected to a corresponding first touch electrode TE1 of the plurality of first touch electrodes TE1 through a via hole provided at the touch insulation layer 165. Therefore, the plurality of second touch electrodes TE2 disposed adjacent to one another along the first direction X or the second direction Y may be connected to one another through the plurality of first touch electrodes TE1. For example, the plurality of second touch electrodes TE2 disposed adjacent to one another along the second direction Y may be connected to one another through the plurality of first touch electrodes TE1.

The touch protection layer 169 may be disposed on the touch insulation layer 165 to cover the second touch electrode layer 167. The touch protection layer 169 may be configured to planarize an upper portion of the touch sensing part 160 and protect the touch sensing part 160. For example, the touch protection layer 169 may be formed of an organic material, but is not limited thereto.

The display apparatus 10 or the display panel according to an embodiment of the present disclosure may further include a functional film 170 which is disposed on the touch sensing part 160.

The functional film 170 may include a reflection preventing layer (or reflection preventing film) which is attached on the touch sensing part 160. For example, the reflection preventing layer may include a circular polarizing layer (or circular polarizing film), but is not limited thereto.

The display apparatus 10 or the display panel according to an embodiment of the present disclosure may further include the supporting member 200 which is disposed at the rear surface of the substrate 100. The supporting member 200 may maintain the other portion, except the bending area BA, of the substrate 100 in a flat state. This may be the same as the supporting member 200 described above with reference to FIGS. 1 and 2, and thus, repeated descriptions thereof is omitted.

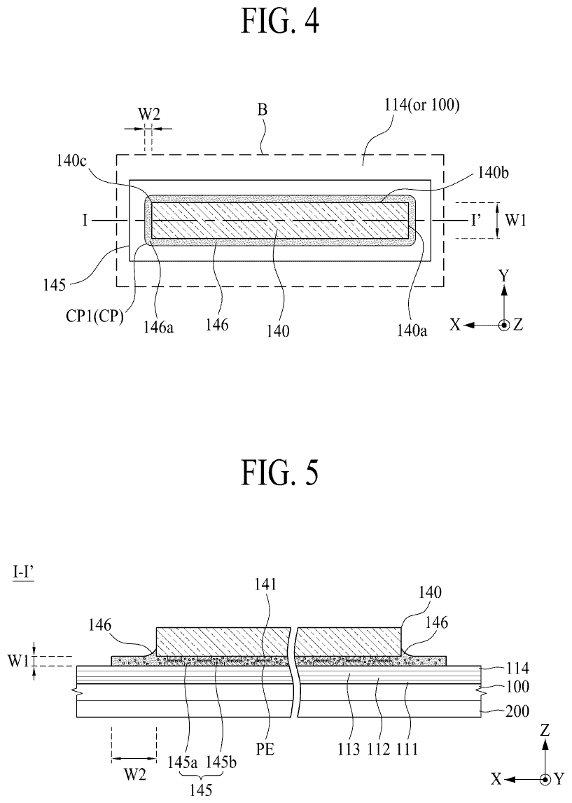

FIG. 4 is an enlarged view schematically illustrating a portion “B” illustrated in FIG. 1. FIG. 5 is a cross-sectional view taken along line I-I′ illustrated in FIG. 4.

Referring to FIGS. 1, 4, and 5, the display apparatus 10 or the display panel according to an embodiment of the present disclosure may further include a chamfer part CP.

The chamfer part CP according to an embodiment of the present disclosure may be disposed or configured at the circuit mounting area CA1 corresponding to a corner portion 140c of the driving integrated circuit 140. For example, the corner portion 140c of the driving integrated circuit 140 is formed (or configured) as the chamfer part CP.

The driving integrated circuit 140 may include a predetermined width W1 and length. For example, the driving integrated circuit 140 may have a rectangular shape having the width (or a short-side length) W1 and the length (or a long-side length). For example, the driving integrated circuit 140 may include a rectangular shape or a hexahedral shape having the rectangular shape, including a short side 140a having the width W1, a long side 140b having the length, and a corner portion 140c between the short side 140a and the long side 140b. For example, a length direction of the driving integrated circuit 140 may be parallel to the gate line Lg or the first direction X.

The chamfer part CP may be formed (or configured) at a corner portion of the circuit mounting area CA1 corresponding to the corner portion 140c of the driving integrated circuit 140. The chamfer part CP may prevent or minimize cracks and/or peeling (or delamination) occurring in the insulating layer (for example, an inorganic insulating layer) disposed (or formed) around the driving integrated circuit 140 due to bending of the display panel or the substrate 100 by distributing (or dispersing) stress concentrated on the corner portion 140c of the driving integrated circuit 140 due to bending of the display panel or the substrate 100. For example, when bending occurs in the display panel or the substrate 100, stress is concentrated on the corner portion 140c of the driving integrated circuit 140, and thus, cracks and/or peeling (or delamination) may occur in the insulating layers 111, 112, 113, and 114 disposed between the driving integrated circuit 140 and the substrate 100 around the corner portion 140c of the driving integrated circuit 140.

The stress occurring on the corner portion 140c of the driving integrated circuit 140 due to bending of the display panel or the substrate 100 may be distributed (or dispersed) by the chamfer part CP without being concentrated on the corner portion 140c of the driving integrated circuit 140. Accordingly, the chamfer part CP may prevent or minimize cracks and/or peeling (or delamination) occurring around the corner portion 140c of the driving integrated circuit 140.

The chamfer part CP may include a corner rounding portion CP1 having a curved surface corresponding to the corner portion 140c of the driving integrated circuit 140. The corner rounding portion CP1 may be configured to have a curved surface at the corner portion of the circuit mounting area CA1 corresponding to the corner portion 140c of the driving integrated circuit 140.

The display apparatus 10 or the display panel according to an embodiment of the present disclosure may further include a resin layer 146.

The resin layer 146 may be disposed at a peripheral area of the driving integrated circuit 140 among the circuit mounting area CA1, and may be formed (or configured) to cover a portion (or a lower side surface) of side surfaces (or sides) 140a and 140b of the driving integrated circuit 140. The chamfer part CP may be formed at a corner portion 146a of the resin layer 146 corresponding to the corner portion 140c of the driving integrated circuit 140. The corner portion 146a of the resin layer 146 or the chamfer part CP may be formed to surround the corner portion 140c of the driving integrated circuit 140. The corner portion 146a of the resin layer 146 or the chamfer part CP may include the corner rounding portion CP1 having a curved surface.

The corner rounding portion CP1 may be formed (or configured) to have a predetermined curvature at the corner portion 146a of the resin layer 146. For example, the corner rounding portion CP1 may have a curvature of 5% to 20% of a total width W1 of the driving integrated circuit 140. For example, the corner rounding portion CP1 or the corner portion 146a of the resin layer 146 may have a curvature of 5% to 20% of the total width W1 of the driving integrated circuit 140.

The display apparatus 10 (or the display panel) according to an embodiment of the present disclosure may further include an anisotropic conductive film 145. The anisotropic conductive film 145 may be disposed (or formed) at an area between the driving integrated circuit 140 and the substrate 100 and around the peripheral area of the driving integrated circuit 140.

The driving integrated circuit 140 may be disposed (or mounted) on an uppermost insulating layer 114 disposed at the circuit mounting area CA1 of the substrate 100 and electrically connected to a pad electrode PE which is disposed (or formed) at the circuit mounting area CA1 of the substrate 100 by using the anisotropic conductive film 145. For example, the driving integrated circuit 140 may be disposed on the passivation layer 114 (or the interlayer insulating layer 113) in the circuit mounting area CA1. The pad electrode PE may be formed (or configured) at the circuit mounting area CA1 to be electrically connected to end portions of each of the plurality of routing lines RL and the plurality of connection lines CL. For example, the pad electrode PE may be formed together with the first touch electrode TE1 or the second touch electrode TE2, but is not limited thereto.

The anisotropic conductive film 145 may include an insulating adhesive 145a and conductive particles 145b.

The insulating adhesive 145a may be made of a thermosetting resin or a photo-curable resin. For example, the insulating adhesive 145a may include an epoxy resin or a polyurethane resin containing a curing agent. The insulating adhesive 145a may be adhered between a rear surface of the driving integrated circuit 140 and the substrate 110. The insulating adhesive 145a may be adhered between the rear surface of the driving integrated circuit 140 and the passivation layer 114 (or interlayer insulating layer 113).

The conductive particles 145b may include a polymer coated with a metal. The conductive particles 145b may be configured to have electrical conductivity only in a specific direction (for example, a vertical direction) within the anisotropic conductive film 145. For example, the conductive particles 145b may have electrical insulation in a horizontal direction. The conductive particles 145b may be electrically connected between a channel (or bump) 141 of the driving integrated circuit 140 and the pad electrode PE. For example, each channel (or bump) 141 of the driving integrated circuit 140 may be electrically connected to a corresponding pad electrode PE through one or more conductive particles 145b by a chip bonding process. Accordingly, the driving integrated circuit 140 may be adhered (or bonded) on the substrate 100 by the insulating adhesive 145a and electrically connected to the pad electrode PE.

The anisotropic conductive film 145 may have a larger size (or an area) than the driving integrated circuit 140. An edge portion of the anisotropic conductive film 145 may not overlap the driving integrated circuit 140. For example, a width W2 between a side surface (or a side) 140a and 140b of the driving integrated circuit 140 and a side surface (or an outer sidewall) of the anisotropic conductive film 145 may be 10% to 20% of the total width W1 of the driving integrated circuit 140, but is not limited thereto. Accordingly, the anisotropic conductive film 145 may be disposed (or formed) at the area between the driving integrated circuit 140 and the substrate 100 and in the peripheral area of the driving integrated circuit 140.

The resin layer 146 may have a thickness thinner than the driving integrated circuit 140. A portion of the resin layer 146 may be in contact or directly in contact with a portion (or a lower side surface) of the side surface (or side) 140a and 140b of the driving integrated circuit 140. The portion of the resin layer 146 may protrude from a portion of the anisotropic conductive film 145 disposed at the peripheral area of the driving integrated circuit 140. The resin layer 146 may include the insulating adhesive 145a of the anisotropic conductive film 145. For example, the resin layer 146 may be made of a same material as the insulating adhesive 145a of the anisotropic conductive film 145. For example, the portion of the resin layer 146 may be formed by a portion of the insulating adhesive 145a of the anisotropic conductive film 145 protruding (or raised) toward the side surface (or side) 140a and 140b of the driving integrated circuit 140. The portion of the insulating adhesive 145a of the anisotropic conductive film 145 may protrude (or be raised) to directly contact the side surface (or side) 140a and 140b of the driving integrated circuit 140 to form (or configure) the resin layer 146. The insulating adhesive 145a of the anisotropic conductive film 145 may be formed (or configured) to have a thickness at which the resin layer 146 may be formed (or configured).

As described above, the display apparatus 10 or the display panel according to an embodiment of the present disclosure may include the chamfer part CP having the corner rounding portion CP1 which is formed (or configured) at the resin layer 146 around the driving integrated circuit 140, and thus, cracks and/or peeling (or delamination) occurring around the corner portion 140c of the driving integrated circuit 140 may be prevented or minimized, and may have improved reliability. Furthermore, the display apparatus 10 or the display panel may implement ESG (Environmental, Social, Governance) performance through process optimization due to a crack (or peeling or delamination) prevention structure including the chamfer part CP.

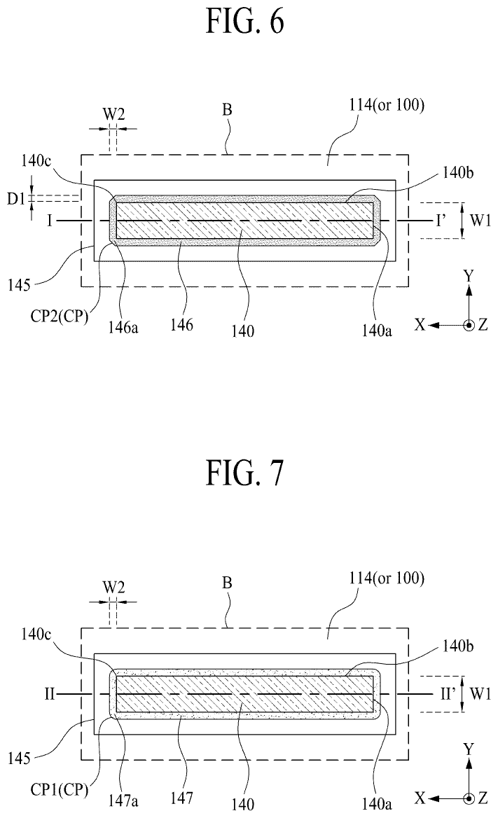

FIG. 6 is another enlarged view schematically illustrating a portion “B” illustrated in FIG. 1. FIG. 6 illustrates an embodiment where the chamfer part in the display apparatus described above with reference to FIGS. 1 to 5 has been modified. In the following description, therefore, only the chamfer part will be described, and the remaining elements are referred to by the same reference numerals as FIGS. 1 to 5, and their repeated descriptions are omitted or will be briefly given. Therefore, descriptions above with reference to FIGS. 1 to 5 may be included in descriptions of FIG. 6. Furthermore, a cross-sectional view taken along line I-I′ illustrated in FIG. 6 is illustrated in FIG. 5.

Referring to FIGS. 1, 5, and 6, in the display apparatus 10 (or the display panel) according to an embodiment of the present disclosure, the chamfer part CP may include a corner chamfer portion CP2 having an inclined surface (or a sloped surface). For example, the chamfer part CP may include the corner chamfer portion CP2 having the inclined surface instead of the corner rounding portion CP1 described above with reference to FIGS. 1 to 5.

The corner chamfer portion CP2 may be formed (or configured) to distribute (or disperse) stress concentrated on the corner portion 140c of the driving integrated circuit 140 due to bending of the display panel or the substrate 100. The corner chamfer portion CP2 may be formed at the corner portion 146a of the resin layer 146 corresponding to the corner portion 140c of the driving integrated circuit 140.

The corner portion 146a of the resin layer 146 or the chamfer part CP may be formed to surround the corner portion 140c of the driving integrated circuit 140. The corner portion 146a of the resin layer 146 or the chamfer part CP may include the corner chamfer portion CP2.

The corner chamfer portion CP2 may have a predetermined inclined surface on the corner portion 146a of the resin layer 146. For example, the corner chamfer portion CP2 may have a distance (or a length) D1 of 5% to 20% of the total width (or an entire short-side length) W1 of the driving integrated circuit 140. The corner chamfer portion CP2 may include an inclined surface of 45 degree. For example, the corner chamfer portion CP2 (or the corner portion 146a) of the resin layer 146 may have a distance (or a length) D1 of 5% to 20% of the total width (or entire short-side length) W1 of the driving integrated circuit 140 and include an inclined surface of 45 degree.

As described above, the display apparatus 10 or the display panel according to an embodiment of the present disclosure may include the chamfer part CP having the corner chamfer portion CP2 which is formed (or configured) at the resin layer 146 around the driving integrated circuit 140, and thus, cracks and/or peeling (or delamination) occurring around the corner portion 140c of the driving integrated circuit 140 may be prevented or minimized, and may have improved reliability. Furthermore, the display apparatus 10 or the display panel may implement ESG (Environmental, Social, Governance) performance through process optimization due to a crack (or peeling or delamination) prevention structure including the chamfer part CP.

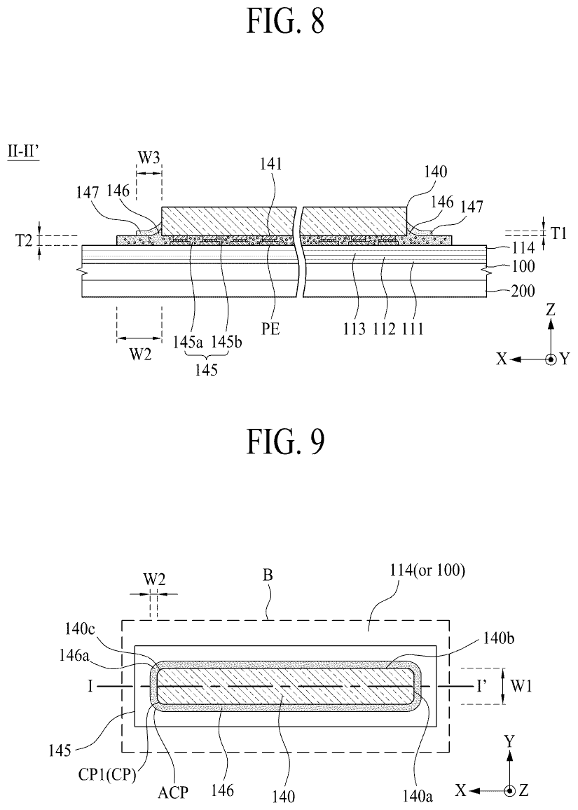

FIG. 7 is another enlarged view schematically illustrating a portion “B” illustrated in FIG. 1. FIG. 8 is a cross-sectional view taken along line II-II′ illustrated in FIG. 7. FIGS. 7 and 8 illustrate an embodiment where an auxiliary resin layer is additionally configured in the display apparatus described above with reference to FIGS. 1 to 5 has been modified. In the following description, therefore, only the auxiliary resin layer will be described, and the remaining elements are referred to by the same reference numerals as FIGS. 1 to 5, and their repeated descriptions are omitted or will be briefly given. Therefore, descriptions above with reference to FIGS. 1 to 5 may be included in descriptions of FIGS. 7 and 8.

Referring to FIGS. 1, 7, and 8, the display apparatus 10 (or the display panel) according to an embodiment of the present disclosure may further include an auxiliary resin layer 147.

The auxiliary resin layer 147 may be configured to cover the resin layer 146 disposed at the peripheral area of the driving integrated circuit 140 and may be formed (or configured) to cover the portion (or lower side surface) of the side surface (or side) 140a and 140b of the driving integrated circuit 140.

The auxiliary resin layer 147 may have a thickness thinner than the driving integrated circuit 140. A portion of the auxiliary resin layer 147 may be in contact or directly in contact with the portion (or lower side surface) of the side surface (or side) 140a and 140b of the driving integrated circuit 140.

The chamfer part CP may be formed at a corner portion 147a of the auxiliary resin layer 147 to distribute (or disperse) stress concentrated on the corner portion 140c of the driving integrated circuit 140. For example, the chamfer part CP may be formed at the corner portion 147a of the auxiliary resin layer 147 corresponding to the corner portion 140c of the driving integrated circuit 140.

The corner portion 147a of the auxiliary resin layer 147 or the chamfer part CP may be formed to surround the corner portion 140c of the driving integrated circuit 140. The corner portion 147a of the auxiliary resin layer 147 or the chamfer part CP may include the corner rounding portion CP1 having a curved surface. For example, the corner rounding portion CP1 may be formed (or configured) at one or more of the corner portion 146a of the resin layer 146 and the corner portion 147a of the auxiliary resin layer 147. For example, the corner rounding portion CP1 may be formed (or configured) in the same manner as each of the corner portion 146a of the resin layer 146 and the corner portion 147a of the auxiliary resin layer 147.

The corner rounding portion CP1 may have a predetermined curvature at the corner portion 147a of the auxiliary resin layer 147. For example, the corner rounding portion CP1 may have the curvature of 5% to 20% of the total width W1 of the driving integrated circuit 140. For example, the corner rounding portion CP1 or the corner portion 147a of the auxiliary resin layer 147 may have the curvature of 5% to 20% of the total width W1 of the driving integrated circuit 140.

The auxiliary resin layer 147 may include a thermosetting resin or a photo-curable resin. The auxiliary resin layer 147 may include an epoxy resin or a polyurethane resin containing a curing agent or may be made of a solder resist. For example, the auxiliary resin layer 147 may be made of a same material as the insulating adhesive 146a of the anisotropic conductive film 145.

The auxiliary resin layer 147 may be formed (or configured) to directly contact the portion (or lower side surface) of the side surface (or side) 140a and 140b of the driving integrated circuit 140 and may be formed (or configured) to have a thickness T1 capable of covering the resin layer 146. The auxiliary resin layer 147 may have a thickness (or height) T1 of 1% to 5% of the total width W1 of the driving integrated circuit 140. For example, the thickness T1 of the auxiliary resin layer 146 may be thinner than a thickness (or height) T2 of the anisotropic conductive film 145, but is not limited thereto.

The auxiliary resin layer 147 may be disposed between the side surface (or side) 140a and 140b of the driving integrated circuit 140 and the side surface (or outer sidewall) of the anisotropic conductive film 145. For example, with respect to the side surface (or side) 140a and 140b of the driving integrated circuit 140, the auxiliary resin layer 147 may have a width W3 of 1% to 10% of the total width W1 of the driving integrated circuit 140. For example, the auxiliary resin layer 147 may not overlap the driving integrated circuit 140. For example, a width (or distance) W3 between the side surface (or side) 140a and 140b of the driving integrated circuit 140 and a side surface (or an outer sidewall) of the auxiliary resin layer 147 may be 1% to 10% of the total width W1 of the driving integrated circuit 140, but is not limited thereto.

Alternatively, the corner rounding portion CP1 (or the corner portion 147a) of the auxiliary resin layer 147 may be changed (or replaced) to the corner chamfer portion CP2 as described above with reference to FIG. 6, and thus, repeated descriptions thereof is omitted.

As described above, the display apparatus 10 or the display panel according to an embodiment of the present disclosure may include the chamfer part CP having the corner rounding portion CP1 which is formed (or configured) at the resin layer 146 and the auxiliary resin layer 147 around the driving integrated circuit 140, and thus, cracks and/or peeling (or delamination) occurring around the corner portion 140c of the driving integrated circuit 140 may be prevented or minimized, and may have improved reliability. Furthermore, the display apparatus 10 or the display panel may implement ESG (Environmental, Social, Governance) performance through process optimization due to a crack (or peeling or delamination) prevention structure including the chamfer part CP.

FIG. 9 is another enlarged view schematically illustrating a portion “B” illustrated in FIG. 1. FIG. 9 illustrates an embodiment where the chamfer part in the display apparatus described above with reference to FIGS. 1 to 8 has been modified. In the following description, therefore, only the chamfer part will be described, and the remaining elements are referred to by the same reference numerals as FIGS. 1 to 8, and their repeated descriptions are omitted or will be briefly given. Therefore, descriptions above with reference to FIGS. 1 to 8 may be included in descriptions of FIG. 9. Furthermore, a cross-sectional view taken along line I-I′ illustrated in FIG. 9 is illustrated in FIG. 5.

Referring to FIGS. 1, 5, and 9, in the display apparatus 10 (or the display panel) according to another embodiment of the present disclosure, the chamfer part CP may be formed (or configured) at the corner portion 140c of the driving integrated circuit 140.

The chamfer part CP may be formed (or configured) to distribute (or disperse) stress concentrated on the corner portion 140c of the driving integrated circuit 140 due to bending of the display panel or substrate 100. The chamfer part CP may be formed (or configured) at the corner portion 140c of the driving integrated circuit 140.

The chamfer part CP according to an embodiment may include a corner rounding portion CP1 having a curved surface which is formed (or configured) at the corner portion 140c of the driving integrated circuit 140.

The corner rounding portion CP1 may have a predetermined curvature at the corner portion 140c of the driving integrated circuit 140 to distribute (or disperse) stress concentrated on the corner portion 140c of the driving integrated circuit 140. For example, the corner rounding portion CP1 may have a curvature of 5% to 20% of the total width W1 of the driving integrated circuit 140. For example, the corner rounding portion CP1 or the corner portion 140c of the driving integrated circuit 140 may have a curvature of 5% to 20% of the total width W1 of the driving integrated circuit 140.

The chamfer part CP according to another embodiment may include a corner chamfer portion having an inclined surface (or a sloped surface) which is formed (or configured) at the corner portion 140c of the driving integrated circuit 140. The corner chamfer portion may be a same or substantially a same as the corner chamfer portion CP2 described above with reference to FIG. 6, and thus, repeated descriptions thereof is omitted or will be briefly given.

The corner chamfer portion may have a predetermined inclined surface at the corner portion 140c of the driving integrated circuit 140. For example, the corner chamfer portion may have a distance (or length) of 5% to 20% of the total width (or entire short-side length) W1 of the driving integrated circuit 140. The corner chamfer portion may include an inclined surface of 45 degree. For example, the corner chamfer portion (or corner portion 146a) of the driving integrated circuit 140 may have a distance (or length) of 5% to 20% of the total width W1 of the driving integrated circuit 140 and include an inclined surface of 45 degree.

The display apparatus 10 (or the display panel) according to another embodiment of the present disclosure may further include a resin layer 146.

The resin layer 146 may be disposed at the peripheral area of the driving integrated circuit 140 in the circuit mounting area CA1 and formed (or configured) to cover the portion (or a lower side surface) of side surfaces (or sides) 140a and 140b of the driving integrated circuit 140. The corner portion 146a of the resin layer 146 may be formed to surround the corner portion 140c of the driving integrated circuit 140 (or the chamfer part CP). For example, the corner portion 146a of the resin layer 146 may be formed to surround the corner portion 140c of the driving integrated circuit 140 or the corner rounding portion CP1. The portion (or a lower side surface) of side surfaces (or sides) 140a and 140b of the driving integrated circuit 140 and the corner rounding portion CP1 may each be directly surrounded by the resin layer 146.

The display apparatus 10 (or the display panel) according to another embodiment of the present disclosure may further include an auxiliary chamfer portion ACP.

The auxiliary chamfer portion ACP may be formed (or configured) in a peripheral area of the driving integrated circuit 140 to distribute (or disperse) stress concentrated on the corner portion 140c of the driving integrated circuit 140 due to bending of the display panel or substrate 100. The auxiliary chamfer portion ACP may be formed (or configured) at the resin layer 146 to correspond to the chamfer part CP of the driving integrated circuit 140. The auxiliary chamfer portion ACP may have a same shape as the chamfer part CP. For example, the auxiliary chamfer portion ACP may include a corner rounding portion having a curvature or a corner chamfer portion having an inclined surface.

The corner portion 146a of the resin layer 146 or the auxiliary chamfer portion ACP may be formed to surround the corner portion 140c of the driving integrated circuit 140. The corner portion 146a of the resin layer 146 or the auxiliary chamfer portion ACP may include a corner rounding portion having a curvature or a corner chamfer portion having an inclined surface corresponding to the shape of the chamfer part CP.

The corner rounding portion of the auxiliary chamfer portion ACP may have a predetermined curvature at the corner portion 146a of the resin layer 146. For example, the corner rounding portion of the auxiliary chamfer portion ACP may have a curvature of 5% to 20% of the total width (or entire short-side length) W1 of the driving integrated circuit 140. For example, the corner rounding portion of the resin layer 146 (or the corner portion 146a) may have a curvature of 5% to 20% of the total width W1 of the driving integrated circuit 140.

The corner chamfer portion of the auxiliary chamfer portion ACP may have a predetermined inclined surface at the corner portion 146a of the resin layer 146. For example, the corner chamfer portion of the auxiliary chamfer portion ACP may have a distance (or length) of 5% to 20% of the total width (or entire short-side length) W1 of the driving integrated circuit 140. The corner chamfer portion of the auxiliary chamfer portion ACP may include an inclined surface of 45 degree. For example, the corner chamfer portion of the resin layer 146 (or the corner portion 146a) may have a distance (or length) of 5% to 20% of the total width W1 of the driving integrated circuit 140 and include an inclined surface of 45 degree.

As described above, the display apparatus 10 or the display panel according to another embodiment of the present disclosure may include the chamfer part CP which is formed (or configured) at the corner portion 140c of the driving integrated circuit 140, and thus, cracks and/or peeling (or delamination) occurring around the corner portion 140c of the driving integrated circuit 140 may be further prevented or minimized, and may further have improved reliability. Furthermore, the display apparatus 10 or the display panel may implement ESG (Environmental, Social, Governance) performance through process optimization due to a crack (or peeling or delamination) prevention structure including the chamfer part CP.

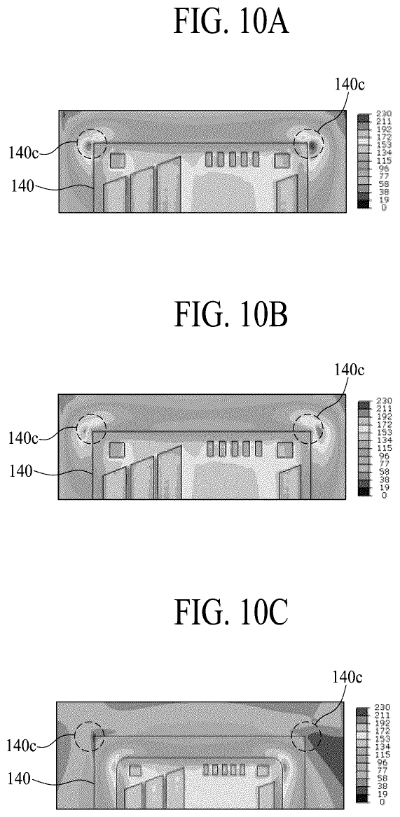

FIG. 10A illustrates a stress applied to an inorganic insulating layer around a corner portion of a driving integrated circuit in a display apparatus according to an experimental example. FIG. 10B illustrates a stress applied to an inorganic insulating layer around a corner portion of a driving integrated circuit in a display apparatus according to an embodiment of the present disclosure described with reference to FIG. 4. FIG. 10C illustrates a stress applied to an inorganic insulating layer around a corner portion of a driving integrated circuit in a display apparatus according to another embodiment of the present disclosure described with reference to FIG. 9. The display apparatus according to the experimental example does not include a chamfer part according to the present disclosure. In FIGS. 10A to 10C, the stress was measured through HAST (highly accelerated stress test) simulation, but is not limited thereto. For example, the HAST simulation is a test method that provides high temperature, high humidity, and high pressure environments to accelerate the occurrence of defects to evaluate the reliability of electronic components.

Referring to FIGS. 10A to 10C, in the stress applied to the inorganic insulating layer around the corner portion 140c of the driving integrated circuit 140, compared to the experimental example, the display apparatus according to an embodiment of the present disclosure may have a stress reduction effect (or stress improvement effect) of reducing stress by approximately 8.4%, and compared to the experimental example, the display apparatus according to another embodiment of the present disclosure may have a stress reduction effect of reducing stress by approximately 10.5%. For example, in the stress applied to the inorganic insulating layer around the corner portion 140c of the driving integrated circuit 140, the stress according to the experimental example may be approximately 227.3 MPa, the stress according to an embodiment of the present disclosure may be approximately 208.2 MPa, and the stress according to another embodiment of the present disclosure may be approximately 203.3 MPa.

The display apparatus 10 or the display panel according to the embodiments of the present disclosure may include the chamfer part CP, and thus, cracks and/or peeling (or delamination) occurring around the corner portion 140c of the driving integrated circuit 140 may be further prevented or minimized, and may further have improved reliability.

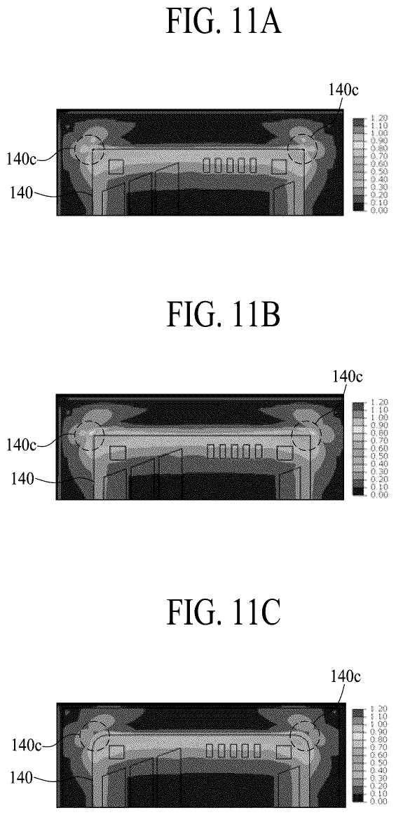

FIG. 11A illustrates peeling damage between a substrate and an inorganic insulating layer around a corner portion of a driving integrated circuit in a display apparatus according to an experimental example. FIG. 11B illustrates peeling damage between a substrate and an inorganic insulating layer around a corner portion of a driving integrated circuit in a display apparatus according to an embodiment of the present disclosure described with reference to FIG. 4. FIG. 11C illustrates peeling damage between a substrate and an inorganic insulating layer around a corner portion of a driving integrated circuit in a display apparatus according to another embodiment of the present disclosure described with reference to FIG. 9. The display apparatus according to the experimental example does not include a chamfer part according to the present disclosure. In FIGS. 11A to 11C, the peeling (or delamination) damage was measured through HAST simulation, but is not limited thereto.

Referring to FIGS. 11A to 11C, in the peeling (or delamination) damage between the substrate and the inorganic insulating layer around the corner portion 140c of the driving integrated circuit 140, compared to the experimental example, the display apparatus according to an embodiment of the present disclosure may have a reduction effect (or improvement effect) of reducing the peeling (or delamination) damage by approximately 35.3%, and compared to the experimental example, the display apparatus according to another embodiment of the present disclosure may have a reduction effect of reducing the peeling (or delamination) damage by approximately 45%. For example, the experimental example may have the peeling (or delamination) damage of approximately 1.12, one embodiment of the present disclosure may have the peeling (or delamination) damage of approximately 0.725, and another embodiment of the present disclosure may have the peeling (or delamination) damage of approximately 0.612.

The display apparatus 10 or the display panel according to the embodiments of the present disclosure may include the chamfer part CP, and thus, peeling (or delamination) occurring around the corner portion 140c of the driving integrated circuit 140 may be further prevented or minimized, and may further have improved reliability.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate having a display area and a non-display area adjacent to the display area, the non-display area including a circuit mounting area;
a pixel part having a plurality of pixels in the display area of the substrate; and
a driving integrated circuit disposed in the circuit mounting area of the substrate and electrically connected to the pixel part,
wherein one or more of a corner portion of the driving integrated circuit and the circuit mounting area corresponding to the corner portion of the driving integrated circuit includes a chamfer part.

2. The display apparatus of claim 1, further comprising a resin layer disposed in a peripheral area of the driving integrated circuit within the circuit mounting area and covering a portion of a side surface of the driving integrated circuit.

3. The display apparatus of claim 2, wherein the chamfer part is formed at a corner portion of the resin layer corresponding to the corner portion of the driving integrated circuit.

4. The display apparatus of claim 3, further comprising an anisotropic conductive film disposed at an area between the driving integrated circuit and the substrate and at the peripheral area of the driving integrated circuit,
wherein a portion of the resin layer protrudes from a portion of the anisotropic conductive film disposed at the peripheral area of the driving integrated circuit so as to contact the portion of the side surface of the driving integrated circuit.

5. The display apparatus of claim 4, wherein:
the anisotropic conductive film includes an insulating adhesive and conductive particles, and
the resin layer is made of a same material as the insulating adhesive of the anisotropic conductive film.

6. The display apparatus of claim 2, further comprising an auxiliary resin layer covering the resin layer disposed at the peripheral area of the driving integrated circuit and covering the portion of the side surface of the driving integrated circuit.

7. The display apparatus of claim 6, wherein the chamfer part is formed at a corner portion of the auxiliary resin layer corresponding to the corner portion of the driving integrated circuit.

8. The display apparatus of claim 7, wherein:
the driving integrated circuit includes a width and a length, and
the auxiliary resin layer has a thickness of 1% to 5% of a total width of the driving integrated circuit and a width of 1% to 10% of a total width of the driving integrated circuit with respect to the side surface of the driving integrated circuit.

9. The display apparatus of claim 8, wherein the corner portion of the driving integrated circuit is formed as the chamfer part.

10. The display apparatus of claim 9, wherein:
the chamfer part includes a corner rounding portion having a curved surface or a corner chamfer portion having an inclined surface,
the driving integrated circuit includes a width and a length,
the corner rounding portion has a curvature of 5% to 20% of a total width of the driving integrated circuit, and
the corner chamfer portion has a width of 5% to 20% of a total width of the driving integrated circuit.

11. A display apparatus, comprising:
a substrate having a display area, a non-display area adjacent to the display area, and a circuit mounting area in the non-display area;
a pixel part having a plurality of pixels in the display area of the substrate; and
a driving integrated circuit disposed in the circuit mounting area of the substrate and electrically connected to the pixel part,
wherein a chamfer part is formed at least at one of a corner portion of the driving integrated circuit or a portion of the circuit mounting area corresponding to the corner portion of the driving integrated circuit.

12. The display apparatus of claim 11, further comprising a resin layer disposed in a peripheral area of the driving integrated circuit and covering a portion of a side surface of the driving integrated circuit.

13. The display apparatus of claim 12, wherein the chamfer part is formed at a corner portion of the resin layer corresponding to the corner portion of the driving integrated circuit.

14. The display apparatus of claim 12, further comprising an anisotropic conductive film disposed between the driving integrated circuit and the substrate, the anisotropic conductive film including an insulating adhesive and conductive particles.

15. The display apparatus of claim 14, wherein the resin layer is made of a same material as the insulating adhesive of the anisotropic conductive film.

16. The display apparatus of claim 12, further comprising an auxiliary resin layer covering the resin layer and at least a portion of the side surface of the driving integrated circuit.
